(19) United States
(12) Patent Application Publication
(10) Pub. No.: US 2026/0293452 A1
(43) Pub. Date: Sep. 24, 2026

(54) DISPLAY DEVICE, METHOD OF MANUFACTURING DISPLAY DEVICE, AND ELECTRONIC DEVICE INCLUDING THE SAME

(71) Applicant: Samsung Display Co., Ltd., Yongin-si (KR)

(72) Inventors: SEON-IL KIM, Yongin-si (KR); SEONHWA CHOI, Yongin-si (KR); JEONG WON KIM, Yongin-si (KR); JUNHONG PARK, Yongin-si (KR); KABJONG SEO, Yongin-si (KR)

(21) Appl. No.: 19/568,352

(22) Filed: Mar. 16, 2026

(30) Foreign Application Priority Data
Mar. 21, 2025 (KR) 10-2025-0036847

(51) Int. Cl. H10K 59/123; H10K 59/12; H10K 59/124; H10K 59/131

(52) U.S. Cl. CPC H10K 59/123; H10K 59/1201; H10K 59/124; H10K 59/131

(57) ABSTRACT

A display device includes a substrate, a thin-film transistor above the substrate, a light-emitting element connected to the thin-film transistor, a first region including a first conductive layer, a second conductive layer, and a third conductive layer sequentially stacked, and a second region spaced apart from the first region, and including one or two of the first conductive layer, the second conductive layer, or the third conductive layer and a planarization layer stacked thereabove, wherein the third conductive layer of the first region is at a higher level than an uppermost one of the first, second, or third conductive layer of the second region, and wherein an upper surface of the uppermost one of the one or two of the first conductive layer, the second conductive layer, or the third conductive layer of the second region conforms to a lower surface of the planarization layer.

### CROSS-REFERENCE TO RELATED APPLICATION

The present application claims priority to, and the benefit of, Korean Patent Application No. 10-2025-0036847, filed on Mar. 21, 2025, in the Korean Intellectual Property Office, the entire disclosure of which is incorporated herein by reference.

### BACKGROUND

### 1. Field

The disclosure relates to a display device, a method of manufacturing the display device, and an electronic device including the same.

### 2. Description of the Related Art

Recently, various types of lightweight and compact flat-panel display devices are being developed. Flat-panel display devices include liquid crystal displays (LCDs), field emission displays (FEDs), plasma display panels (PDPs), and organic light-emitting displays (OLEDs).

Among flat-panel displays, organic light-emitting diodes (OLEDs) display images using organic light-emitting diodes (OLEDs), which emit light through the recombination of electrons and holes. These organic light-emitting diode displays are receiving attention as next-generation displays because they have fast response speeds and operate with low power consumption.

The background technology described above is information that the inventor possessed for deriving the disclosure or acquired in the process of deriving the disclosed embodiments, and cannot necessarily be considered as publicly known technology disclosed to the general public prior to the application for the disclosure.

### SUMMARY

The disclosure provides a display device with improved stability and pixel electrode flatness, and an electronic device including the same.

The aspects of the disclosure are not limited to the aspects mentioned above, and other aspects of the present disclosure that are not mentioned can be understood by the following description and will be more clearly understood by the embodiments of the disclosure. In some embodiments, the aspects of the disclosure may be realized through the means and their combinations described in the claims.

One or more embodiments of the disclosure discloses a display device including a substrate, a thin-film transistor above the substrate, a light-emitting element electrically connected to the thin-film transistor, a first region between the thin-film transistor and the light-emitting element, and including a first conductive layer, a second conductive layer, and a third conductive layer sequentially stacked, and a second region between the thin-film transistor and the light-emitting element, spaced apart from the first region, and including one or two of the first conductive layer, the second conductive layer, or the third conductive layer and a planarization layer stacked thereabove, wherein the third conductive layer of the first region is at a higher level than an uppermost one of the one or two of the first conductive layer, the second conductive layer, or the third conductive layer of the second region, and wherein an upper surface of the uppermost one of the one or two of the first conductive layer, the second conductive layer, or the third conductive layer of the second region conforms to a lower surface of the planarization layer.

A height of the first region may be substantially equal to a height of the second region.

The light-emitting element may include a pixel electrode above the third conductive layer of the first region and the planarization layer of the second region, a common electrode, and an intermediate layer between the pixel electrode and the common electrode and including an organic material, wherein the third conductive layer of the first region and the planarization layer of the second region are at a same level.

The pixel electrode may be electrically connected to the third conductive layer of the first region.

The third conductive layer of the first region might not overlap with the planarization layer.

The display device may further include a third region spaced apart from the second region and including the second conductive layer, the third conductive layer, and the planarization layer sequentially stacked.

A height of the second region may be substantially equal to a height of the third region.

The display device may further include a first insulating layer between the first conductive layer of the first region and the second conductive layer of the first region, and a second insulating layer between the second conductive layer of the first region and the third conductive layer of the first region.

The second insulating layer may be between the second conductive layer of the third region and the third conductive layer of the third region.

One or more other embodiments of the present disclosure provides a method of manufacturing a display device, the method including forming a thin-film transistor above a substrate, forming a first conductive layer above an insulating layer covering the thin-film transistor, and patterning the first conductive layer, forming a second conductive layer above a first insulating layer covering a patterned first conductive layer, and patterning the second conductive layer, forming a third conductive layer above a second insulating layer covering a patterned second conductive layer, forming a planarization layer above the third conductive layer, depositing a photoresist above the planarization layer and the third conductive layer, patterning the photoresist, etching the planarization layer and the third conductive layer using a patterned photoresist as a mask, and forming a light-emitting element electrically connected to an etched third conductive layer, wherein a first region and a second region are spaced apart between the thin-film transistor and the light-emitting element, the first region including the first conductive layer, the second conductive layer, and the third conductive layer sequentially stacked, and the second region including the first conductive layer, the third conductive layer, and the planarization layer are sequentially stacked.

The method may further include etching the third conductive layer to remove a portion of the third conductive layer between the first region and the second region.

A patterned planarization layer may be in the second region.

A height of the first region may be equal to a height of the second region.

The light-emitting element may include a pixel electrode above the etched third conductive layer and the planarization layer, a common electrode, and an intermediate layer between the pixel electrode and the common electrode and including an organic material, wherein the etched third conductive layer and the planarization layer are at a same level.

The etching of the planarization layer and the third conductive layer may include dry etching.

The method may further include, after the etching the planarization layer and the third conductive layer, stripping the photoresist.

The planarization layer may include at least one of siloxane, silica, polysilsesquioxane, silicon oxycarbide, or low-k silicon.

The etching the planarization layer and the third conductive layer may include forming a third region spaced apart from the second region and including the second conductive layer, the third conductive layer, and the planarization layer are sequentially stacked.

A height of the second region may be substantially equal to a height of the third region.

One or more other embodiments of the present disclosure discloses an electronic device including a memory configured to store at least one program, a processor configured to operate by executing the at least one program, a display device configured to receive data from the processor and to provide visual information, and a power module configured to supply power to the display device, wherein the display device includes a substrate, a thin-film transistor above the substrate, a light-emitting element electrically connected to the thin-film transistor, and a first region and a second region spaced apart between the thin-film transistor and the light-emitting element, the first region including a first conductive layer, a second conductive layer, and a third conductive layer sequentially stacked, and the second region including one or two of the first conductive layer, the second conductive layer, or the third conductive layer, and a planarization layer thereabove, wherein the third conductive layer of the first region is at a higher level than an uppermost one of the one or two of the first conductive layer, the second conductive layer, or the third conductive layer of the second region, and wherein an upper surface of the uppermost one of the one or two of the first conductive layer, the second conductive layer, or the third conductive layer of the second region conforms to a lower surface of the planarization layer.

### BRIEF DESCRIPTION OF THE DRAWINGS

The following drawings attached to this specification illustrate embodiments of the present disclosure and, together with the detailed description of the disclosure described below, serve to further understand the technical idea of the disclosure; therefore, the disclosure should not be interpreted as being limited to matters described in such drawings:

FIG. 1 is a plan view schematically illustrating an example of a display device according to one or more embodiments of the disclosure;

FIG. 2 is a perspective view schematically illustrating the bending shape of the display device of FIG. 1;

FIG. 3 is a block diagram schematically illustrating the structure of the display device of FIG. 1;

FIG. 4 is a cross-sectional view schematically illustrating one or more embodiments and taken along the line A-A′ of FIG. 1;

FIG. 5 is an image showing the appearance of photoresist remaining between conventional conductive layers;

FIG. 6 is a cross-sectional view schematically illustrating an example of a laminated shape of conductive layers according to one or more embodiments of the disclosure;

FIGS. 7 to 12 are cross-sectional views schematically illustrating one or more embodiments of a method of manufacturing a stacked shape of the conductive layers of FIG. 6;

FIG. 13 and FIG. 14 are cross-sectional views schematically illustrating one or more embodiments of a stacked shape of conductive layers according to one or more other embodiments of the disclosure;

FIG. 15 is a block diagram of an electronic device according to one or more embodiments; and

FIG. 16 is schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

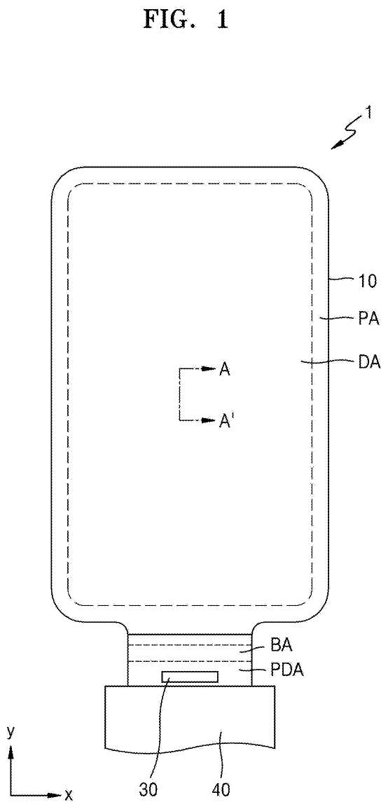

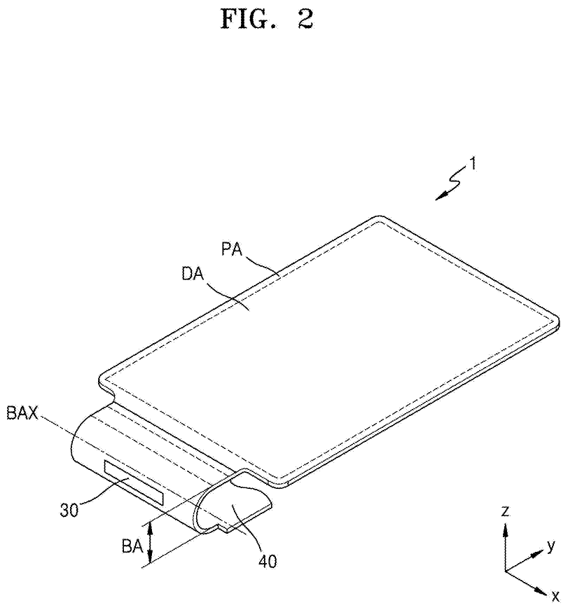

FIG. 1 is a plan view schematically illustrating one or more embodiments of a display device 1 according to one or more embodiments of the disclosure, and FIG. 2 is a perspective view schematically illustrating a bending shape of the display device of FIG. 1.

Referring to FIGS. 1 and 2, the display device 1 is a device that displays a moving image or still image, and may display a screen on a display panel 10 or perform input and output of data. The display device 1 may be used not only as the display screen for portable electronic devices such as a mobile phone, a smartphone, a tablet personal computer, a mobile communication terminal, an electronic notebook, an electronic book, a portable multimedia player (PMP), a navigation device, an Ultra Mobile PC (UMPC), but also as the display screen for various electronic devices such as a television, a laptop, a monitor, a billboard, an Internet of Things (IOT) device, etc. In some embodiments, the display device 1 according to one or more embodiments can be used in electronic devices, such as wearable devices, including a smart watch, a watch phone, a glasses-type display, and a head-mounted display (HMD). In some embodiments, the display device 1 according to one or more embodiments can be used as a display for various electronic devices, such as a dashboard of an automobile, a center information display (CID) placed on a center fascia or dashboard of an automobile, a room mirror display replacing a side mirror of an automobile, and a display placed on the back of a front seat as entertainment for the rear seats of an automobile.

The display device 1 according to one or more embodiments of the disclosure may include a display area DA in which a plurality of pixels is positioned, and a peripheral area PA positioned outside the display area DA. In some embodiments, the peripheral area PA may include a pad area PDA which is positioned on one side of the display area DA and an area to which various electronic components, such as an integrated circuit 30 or a flexible circuit board 40 are electrically attached, and a bending area BA between the display area DA and the pad area PDA. The display area DA, the peripheral area PA, the pad area PDA, and the bending area BA may be partitioned on the substrate.

Meanwhile, FIG. 1 is a plan view illustrating the shape of a substrate, etc. during the manufacturing process of the display device 1, and the substrate, etc. may have a bending area BA bent based on a bending axis BAX extending in the first direction x, as illustrated in FIG. 2. At this time, the bending direction is set so that the pad area PDA is behind the display area DA. Accordingly, the area of the peripheral area PA perceived by the user can be reduced or minimized.

A circuit cover can be attached to the integrated circuit 30 and flexible circuit board 40 of the pad area PDA. The circuit cover can protect the integrated circuit 30 and the flexible circuit board 40 from mechanical shock, and can add waterproofing and insulation performance to the integrated circuit 30 and the flexible circuit board 40.

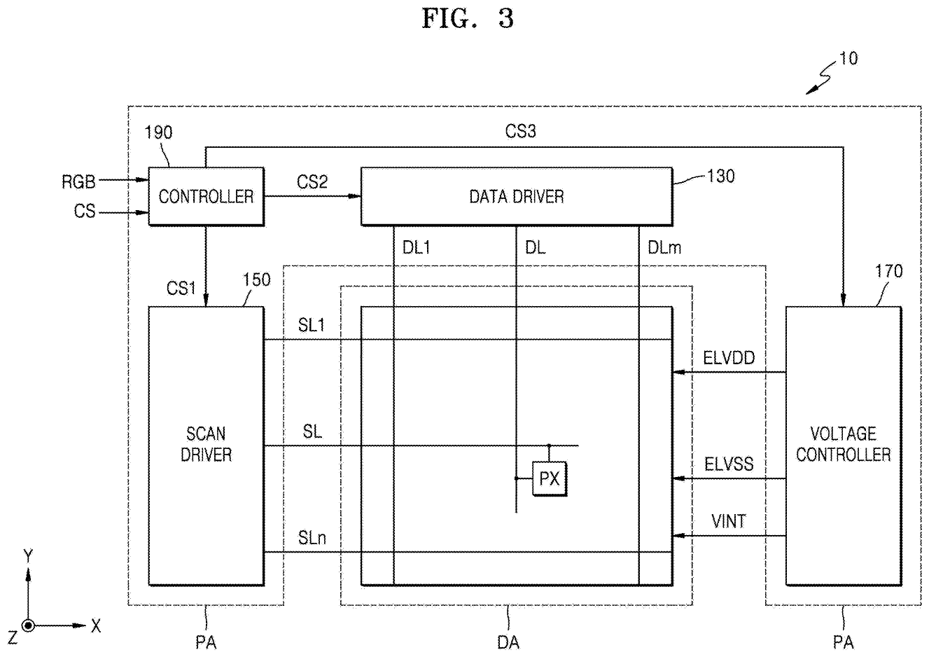

FIG. 3 is a block diagram schematically illustrating the structure of the display device of FIG. 1.

Referring to FIG. 3, a plurality of scan lines SL1, . . . , SLn extending along a first direction x, a plurality of data lines DL1, . . . , DLm extending along a second direction y that is perpendicular to the first direction x, and a plurality of sub-pixels PX may be positioned in the display area DA. At this case, m and n are each natural numbers.

The wirings capable of applying electrical signals to a plurality of sub-pixels PX may include a plurality of scan lines SL1, . . . , SLn, a plurality of data lines DL1, . . . , DLm, etc. A plurality of scan lines SL1, . . . , SLn may be arranged in a plurality of rows extending, for example, in a first direction x to transmit scan signals to sub-pixels PX, and a plurality of data lines DL1, . . . , DLm may be positioned, for example, in a plurality of columns extending in a second direction y to transmit data signals to the sub-pixels PX, and the plurality of sub-pixels PX may be positioned at intersections of the plurality of scan lines SL1, . . . , SLn and the plurality of data lines DL1, . . . , DLm.

Each sub-pixel PX can contain a light-emitting element that can emit red, green, blue, or white light. For example, each sub-pixel PX may include, but is not limited to, an organic light-emitting diode (OLED) as a light-emitting element.

In the peripheral area PA, a data driver 130 that provides data signals to the display area DA, a scan driver 150 that provides scan signals to the display area DA, a voltage controller 170 that controls voltages supplied to the display area DA, and a controller 190 that controls the data driver 130, the scan driver 150, and the voltage controller 170 may be positioned.

The voltage controller 170 may generate and may control a first voltage ELVDD, a second voltage ELVSS, and an initialization voltage VAINT provided to the display area DA.

The first voltage ELVDD, the second voltage ELVSS, and the initialization voltage VAINT may be applied to a plurality of sub-pixels PX. For example, the first voltage ELVDD may be a positive voltage, and the second voltage ELVSS may be a negative voltage or a ground voltage. That is, the second voltage ELVSS may have a lower level than the first voltage ELVDD.

The controller 190 may receive image signals RGB and control signals CS from the outside (e.g., a system board). The controller 190 may convert the data format of image signals RGB to match the interface specifications of the data driver 130 and generate image data DATA. The controller 190 may provide image data whose data format has been converted to the data driver 130.

The controller 190 may generate and may output a first control signal CS1 and a second control signal CS2 in response to a control signal CS provided from the outside. The first control signal CS1 may be defined as a scan control signal, and the second control signal CS2 may be defined as a data control signal. The first control signal CS1 may be provided to the scan driver 150. The second control signal CS2 may be provided to the data driver 130.

The scan driver 150 may generate a plurality of scan signals in response to the first control signal CS1. A plurality of scan signals may be applied to a plurality of sub-pixels PX via a plurality of scan lines SL1, . . . , SLn.

The data driver 130 may generate a plurality of data voltages corresponding to image data DATA in response to the second control signal CS2. A plurality of data voltages may be applied to a plurality of sub-pixels PX via data lines DL1, . . . , DLm. The data driver 130 may concurrently or substantially simultaneously provide (to data lines DL1, . . . , DLm) data voltages generated in units of sub-pixel rows in the plurality of sub-pixels PX.

The plurality of sub-pixels PX may receive a plurality of data voltages in response to a plurality of scan signals. The plurality of sub-pixels PX may display an image by emitting light with a brightness corresponding to a plurality of data voltages. The plurality of sub-pixels PX may display the image by emitting light sequentially or concurrently or substantially simultaneously.

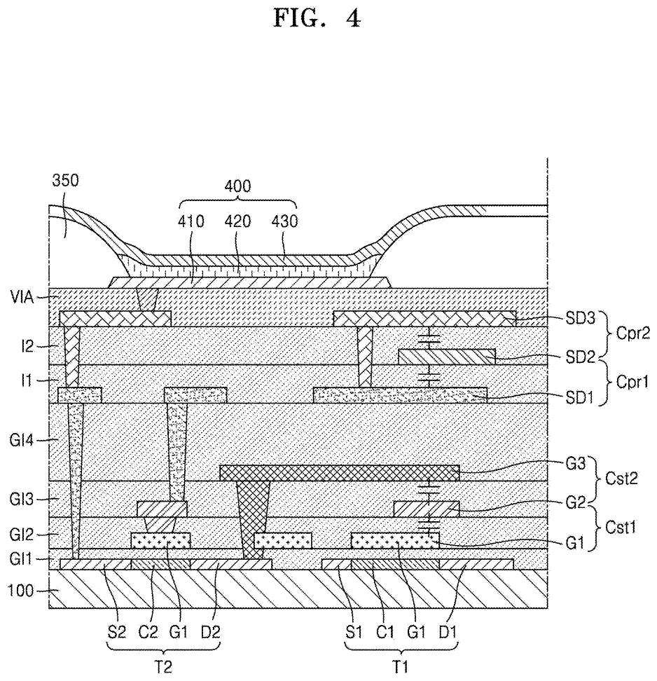

FIG. 4 is a cross-sectional view schematically illustrating an example taken along the line A-A′ of FIG. 1.

Referring to FIG. 4, a display device (1 or FIG. 1) according to one or more embodiments of the present disclosure may include a substrate 100, at least two thin-film transistors T1 and T2 on the substrate 100, a first storage capacitor Cst1 on the at least two thin-film transistors T1 and T2, a second storage capacitor Cst2 on the first storage capacitor Cst1, a first capacitor Cpr1 on the second storage capacitor Cst2, a second capacitor Cpr2 on the first capacitor Cpr1, and a light-emitting element 400 located on the second capacitor Cpr2 and electrically connected to at least one of the thin-film transistors T1 and T2.

In some embodiments, the substrate 100 may include a transparent glass material containing SiO2 as a main component. However, it is not limited thereto, and the substrate 100 may include a transparent plastic material. Plastic materials may be polyethersulfone (PES), polyacrylate (PAR), polyetherimide (PEI), polyethylene naphthenate (PEN), polyethylene terephthalate (PET), polyphenylene sulfide (PPS), polyarylate, polyimide, polycarbonate (PC), cellulose triacetate (TAC), cellulose acetate propionate (CAP), etc.

At least two thin-film transistors T1 and T2 may be arranged on the substrate 100. However, this is not limited thereto, and the number of thin-film transistors may be three or more.

In one or more embodiments, a buffer layer may be formed between the substrate 100 and the two thin-film transistors T1 and T2. The buffer layer may block impurities during the crystallization process for forming polycrystalline silicon, thereby improving the characteristics of the polycrystalline silicon, and may provide a flat surface on the buffer layer.

Meanwhile, the two thin-film transistors T1 and T2 may be a first transistor T1 and a second transistor T2, respectively. The first transistor T1 may be referred to as a driving transistor, and the second transistor T2 may be referred to as a switching transistor or a scan transistor.

The first transistor T1 may include a first semiconductor layer and a first gate electrode G1. In some embodiments, the first semiconductor layer may include a first source region S1 and a first drain region D1 formed by doping impurities on opposite sides of the first channel region C1. In this regard, the impurity varies depending on the type of the first transistor T1 and may include an N-type impurity or a P-type impurity. That is, the first channel region C1, the first source region S1 positioned on one side of the first channel region C1, and the first drain region D1 positioned on another side of the first channel region C1 may be referred to as the first semiconductor layer.

The first source region S1 or the first drain region D1 formed by doping may be interpreted as the source electrode (or the first driving electrode) or the drain electrode (or the second driving electrode) of the first transistor T1 depending on the case. In some embodiments, the positions of the first source region S1 and the first drain region D1 may be swapped depending on the impurities doped into the first semiconductor layer.

The first semiconductor layer may include polycrystalline silicon. For example, the first semiconductor layer may be a layer including low-temperature polycrystalline silicon (LTPS), but is not limited thereto. In some embodiments, the first semiconductor layer may include an oxide semiconductor.

A first gate-insulating layer GI1 may be formed on the first semiconductor layer to cover the same. A first gate electrode G1 may be formed on the first gate-insulating layer GI1. The first gate electrode G1 may form a first transistor T1 together with the first semiconductor layer. The first transistor T1 may receive the first voltage ELVDD from the first source region S1 and may provide a driving current to the light-emitting element 400.

Meanwhile, as described above, the second transistor T2 may be positioned on the substrate 100. The second transistor T2 may include a second semiconductor layer and a first gate electrode G1. In this regard, the first gate electrode G1 of the second transistor T2 and the first gate electrode G1 of the first transistor T1 may be arranged spaced apart from each other on the same layer on the first gate-insulating layer GI1. That is, by stacking a metal layer on the first gate-insulating layer GI1 and then patterning the same, the first gate electrode G1 of the second transistor T2 and the first gate electrode G1 of the first transistor T1 may be formed, respectively. However, this is not limited thereto and the second transistor T2 may not be located on the same layer as the first transistor T1.

The second semiconductor layer may include a second source region S2 and a second drain region D2 formed by doping impurities on opposite sides of the second channel region C2. In this regard, the impurities vary depending on the type of the second transistor T2 and may include N-type impurities or P-type impurities.

The second source region S2 or second drain region D2 formed by doping may be interpreted as the source electrode or drain electrode of the second transistor T2 depending on the case. In some embodiments, the positions of the second source region S2 and the second drain region D2 may be swapped depending on the impurities doped into the second semiconductor layer.

The second semiconductor layer may include polycrystalline silicon. For example, the second semiconductor layer may be a layer including low-temperature polycrystalline silicon (LTPS), but is not limited thereto. In some embodiments, the second semiconductor layer may include an oxide semiconductor.

A first gate-insulating layer GI1 may be formed on the second semiconductor layer to cover the same. The first gate electrode G1 may be formed on the first gate-insulating layer GI1. The first gate electrode G1 may form the second transistor T2 together with the second semiconductor layer. The second transistor T2 may perform a switching function to control brightness and color by receiving a scan signal and delivering an accurate voltage (or current) to a corresponding pixel.

A second gate-insulating layer GI2 covering the first transistor T1 and the second transistor T2 may be formed. A second gate electrode G2, which may be an upper electrode of a first storage capacitor Cst1, may be formed on the second gate-insulating layer GI2. In some embodiments, the second gate electrode G2 may form a first storage capacitor Cst1 together with the first gate electrode G1 of the first transistor T1.

That is, the first gate electrode G1 may function as the gate electrode of the first transistor T1 and the lower electrode of the first storage capacitor Cst1. As a result, the integration level of the display device 1 can be increased, thereby providing a high-quality image. However, the present disclosure is not limited thereto. As one or more other embodiments, the lower electrode of the first storage capacitor Cst1 may be a separate and independent component from the first gate electrode G1 of the first transistor T1.

A third gate-insulating layer GI3 may be formed on the second gate electrode G2 and may cover the same. A third gate electrode G3, which may be an upper electrode of a second storage capacitor Cst2, may be formed on the third gate-insulating layer GI3. In some embodiments, the third gate electrode G3 may form the second storage capacitor Cst2 together with the second gate electrode G2, which may be the upper electrode of the first storage capacitor Cst1.

The first storage capacitor Cst1 and the second storage capacitor Cst2 may store the voltage applied to the first gate electrode G1 of the first transistor T1. The amount of driving current flowing through the first transistor T1 may be determined based on the voltage stored in the first storage capacitor Cst1 and the second storage capacitor Cst2. Based on the driving current, the light-emitting element 400 may emit light.

Meanwhile, the first storage capacitor Cst1 may form a dual capacitor together with the second storage capacitor Cst2. In case that the first storage capacitor Cst1 and the second storage capacitor Cst2 form a dual capacitor, the stability of the pixel voltage may be improved by increasing the capacitance (electrostatic capacity), and accordingly, the voltage stored by the dual capacitor may be maintained more stably, so that the uniformity of the screen of the display device 1 may be improved. However, this is not necessarily limited thereto, and the storage capacitor may be a single capacitor.

A fourth gate-insulating layer GI4 may be formed on the second storage capacitor Cst2 and may cover the same. A first conductive layer SD1 capable of applying current to a first source region S1 of the first transistor T1 or a second source region S2 of the second transistor T2 may be located on the fourth gate-insulating layer GI4. Alternatively, the first conductive layer SD1 may receive current from the first drain region D1 of the first transistor T1 or the second drain region D2 of the second transistor T2.

A first insulating layer I1 may be formed on the first conductive layer SD1 and may cover the same. A second conductive layer SD2 that forms a first capacitor Cpr1 together with the first conductive layer SD1 may be located on the first insulating layer I1. The first capacitor Cpr1 may be referred to as a first program capacitor Cpr1, for example.

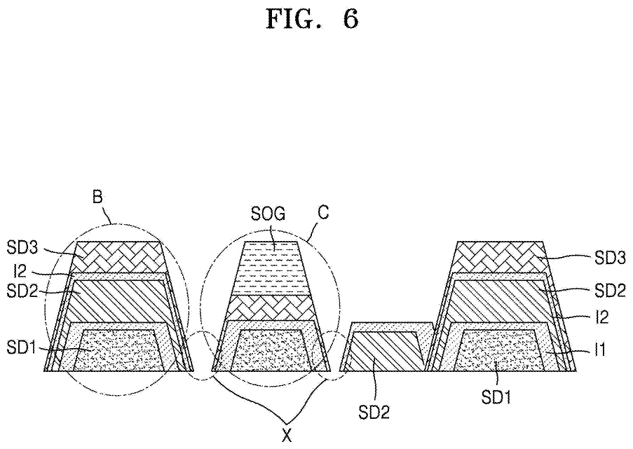

A second insulating layer I2 may be formed on the second conductive layer SD2 and may cover the same. A third conductive layer SD3 which, forms a second capacitor Cpr2 together with a second conductive layer SD2 may be located on the second insulating layer I2. The second capacitor Cpr2 may, for example, be referred to as a second program capacitor Cpr2. In some embodiments, a planarization layer (see SOG in FIG. 6) may be placed on a portion of the third conductive layer SD3, which will be described in detail later in FIG. 6 and below. The first capacitor Cpr1 and the second capacitor Cpr2 may initialize the first voltage ELVDD applied to the first transistor T1. Through the initialization of the first voltage ELVDD, residual voltage of all elements within the sub-pixel circuit may be removed, and a reference state for new driving may be established.

Meanwhile, the first capacitor Cpr1, together with the second capacitor Cpr2, may form a dual capacitor. In case that the first capacitor Cpr1 and the second capacitor Cpr2 form a dual capacitor, the stability of the pixel voltage may be improved by increasing the capacitance. However, it is not necessarily limited thereto, and the program capacitor may be a single capacitor.

Meanwhile, the first gate-insulating layer GI1, the second gate-insulating layer GI2, the third gate-insulating layer GI3, the fourth gate-insulating layer GI4, the first insulating layer I1 and the second insulating layer I2 may each include silicon nitride and/or silicon oxide.

In some embodiments, the first gate electrode G1, the second gate electrode G2, the third gate electrode G3, the first conductive layer SD1, the second conductive layer SD2, and the third conductive layer SD3 may each include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu).

Meanwhile, an organic insulating layer VIA covering the third conductive layer SD3 and the planarization layer (see SOG in FIG. 6) may be formed. The organic insulating layer VIA may include an organic material, such as imide-based polymers, general-purpose polymers, such as polymethylmethacrylate (PMMA) or polystyrene (PS), polymer derivatives having phenolic groups, acrylic polymers, aryl ether polymers, amide-based polymers, fluorinated polymers, p-xylene-based polymers, vinyl alcohol-based polymers, and blends thereof, or may include a laminated film of an organic material and an inorganic material.

A light-emitting element 400 electrically connected to the first transistor T1 or the second transistor T2 through the third conductive layer SD3 may be positioned on the organic insulating layer VIA. The light-emitting element 400 may include a pixel electrode 410, a common electrode 430, and an intermediate layer 420 positioned between the pixel electrode 410 and the common electrode 430 and including a light-emitting layer. The light-emitting element 400 may be, for example, an organic light-emitting element containing an organic material.

In one or more embodiments, the pixel electrode 410 may be an anode of the light-emitting element 400, and the common electrode 430 may be a cathode of the light-emitting element 400. However, the present disclosure is not limited thereto, and depending on the driving method of the display device 1, the pixel electrode 410 may be a cathode of the light-emitting element 400, and the common electrode 430 may be an anode of the light-emitting element 400. In case that holes and electrons are injected into the intermediate layer 420 from the pixel electrode 410 and the common electrode 430, respectively, and the exciton formed by combining the injected holes and electrons drops from the excited state to the ground state, light emission may occur.

Meanwhile, the pixel electrode 410 may be electrically connected to the first transistor T1 or the second transistor T2 through the third conductive layer SD3. In some embodiments, the pixel electrode 410 may be a (semi)transparent electrode or a reflective electrode. In case that the pixel electrode 410 is a (semi)transparent electrode, it may include, for example, ITO, IZO, ZnO, In2O3, IGO or AZO. In case that a pixel electrode 410 is a reflective electrode, the pixel electrode 410 may have a reflective film including Ag, Mg, Al, Pt, Pd, Au, Ni, Nd, Ir, Cr, and compounds thereof, and a layer formed using ITO, IZO, ZnO, In2O3, IGO, or AZO. The present disclosure is not limited thereto, and the pixel electrode 410 may include various materials, and its structure may also be modified in various ways, such as being single-layered or multi-layered.

A pixel definition film 350 covering the edge of the pixel electrode 410 may be positioned on the organic insulating layer VIA. The pixel definition film 350 has an opening corresponding to each pixel, that is, an opening that exposes at least a portion of the light-emitting element 400, thereby defining the pixel. At this time, the opening may be a light-emitting region. In some embodiments, the pixel definition film 350 may reduce or prevent the likelihood of arcs or the like occurring between the edge of the pixel electrode 410 and the common electrode 430 by increasing the distance between them. The pixel definition film 350 may include an organic material, such as polyimide or hexamethyldisiloxane (HMDSO).

An intermediate layer 420 may be formed on the pixel electrode 410 exposed through the opening of the pixel definition film 350. The intermediate layer 420 may include a low molecular weight or high molecular weight material. When a low-molecular-weight substance is included, the intermediate layer 420 may include a hole injection layer (HIL), a hole transport layer (HTL), an emission layer (EML), an electron transport layer (ETL), and an electron injection layer (EIL) in a single or composite stacked structure, and may include various organic materials, such as copper phthalocyanine (CuPc), N, N-di(naphthalene-1-yl)-N, N′-diphenyl-benzidine (NPB), and tris-8-hydroxyquinoline aluminum (Alq3). These layers may be formed by a vacuum deposition method.

In case that the intermediate layer 420 includes a polymer material, the HTL and the EML may be included. At this time, the HTL may include PEDOT, and the light-emitting layer may include a polymer material, such as poly-phenylenevinylene (PPV) and polyfluorene. The structure of the intermediate layer 420 is not limited to that described above and may have various configurations. For example, the intermediate layer 420 may include a single layer that spans the plurality of pixel electrodes 410, or may include a layer patterned to correspond to each of the plurality of pixel electrodes 410.

A second voltage ELVSS may be applied to the common electrode 430, and the common electrode 430 may be arranged to cover the display area (see DA in FIG. 1). That is, the common electrode 430 may be integrally formed to cover a plurality of light-emitting elements 400. The common electrode 430 may be a (semi)transparent electrode or a reflective electrode. In case that the common electrode 430 is a (semi)transparent electrode, the common electrode 430 may include a layer including a low work function metal, such as Li, Ca, LiF/Ca, LiF/Al, Al, Ag, Mg, and compounds thereof, and a (semi)transparent conductive layer including ITO, IZO, ZnO, or In2O3. In case that the common electrode 430 is a reflective electrode, it may include a layer including Li, Ca, LiF/Ca, LiF/Al, Al, Ag, Mg, and compounds thereof. The configuration and materials of the common electrode 430 are not limited to these embodiments, and various modifications may be made thereon.

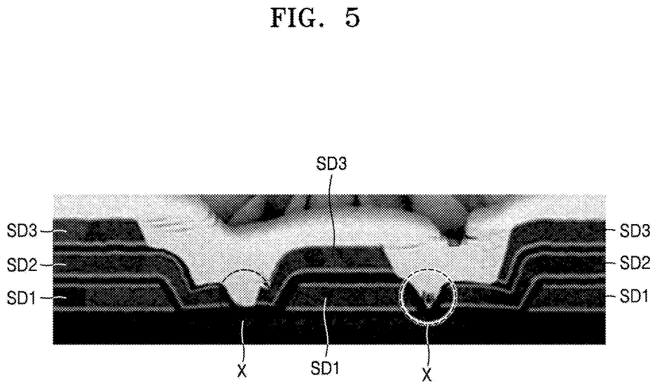

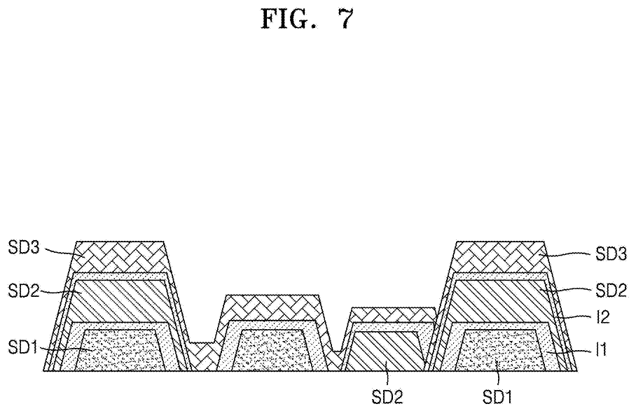

FIG. 5 is an image showing a state in which a photoresist remains between conventional conductive layers, FIG. 6 is a cross-sectional view schematically illustrating an example of a stacked shape of conductive layers according to one or more embodiments of the present disclosure, and FIGS. 7 to 12 are cross-sectional views schematically illustrating an example of a method of manufacturing the stacked shape of conductive layers of FIG. 6.

The first conductive layer SD1, second conductive layer SD2, and third conductive layer SD3 of FIG. 4 are illustrated as being located on flat insulating layers without any bent portions, unlike the first conductive layer SD1, second conductive layer SD2, and third conductive layer SD3 of FIG. 6. This depiction in FIG. 4 is provided for the convenience of explanation, and in actual stacking of components of the display device 1, the components may be stacked in an uneven manner, as illustrated in FIG. 5 or FIG. 6.

Referring first to FIG. 5, in the fabrication of a conventional display device, after forming the thin-film transistor T1 or T2 on the substrate 100, the first conductive layer SD1 is formed on an insulating layer covering the thin-film transistor T1 or T2 and is patterned. The second conductive layer SD2 is then formed on the first insulating layer I1 covering the patterned first conductive layer SD1 and is patterned. Subsequently, the third conductive layer SD3 is formed on the second insulating layer I2 covering the patterned second conductive layer SD2. Thereafter, unlike the embodiments of the present disclosure to be described later, a step region between the first conductive layer SD1, the second conductive layer SD2, and the third conductive layer SD3 is filled with the planarization layer SOG. The photoresist PR is then deposited on the third conductive layer SD3 and the planarization layer SOG, and without patterning the third conductive layer SD3 beforehand, the photoresist PR is immediately stacked on the third conductive layer SD3, and then the third conductive layer SD3 is patterned.

Due to this, as illustrated in FIG. 5, the photoresist PR may remain in the space X between the first region (see B of FIG. 6), where the first conductive layer SD1, the second conductive layer SD2, and the third conductive layer SD3 are sequentially stacked, and the second region (see C of FIG. 6), where the first conductive layer SD1 and the third conductive layer SD3 are sequentially stacked. That is, as illustrated in FIG. 5, the photoresist PR could not be completely stripped and would remain in the space X between the first region B and the second region C that were spaced apart from each other. Accordingly, during a process, such as etching the metal layer under the remaining photoresist PR, the underlying metal layer could remain masked by the remaining photoresist PR. As a result, current could flow along the remaining lower metal layer.

However, in the display device 1 according to the embodiments of the present disclosure, which is manufactured through the fabrication process described below, there is no risk of the photoresist PR remaining in the space X between the first region B and the second region C. Accordingly, the metal pattern underlying the photoresist PR also does not remain, thereby reducing or preventing the likelihood of the formation of unintended current paths, and thereby enhancing the reliability of the display device 1 and the electronic apparatus including the same.

In some embodiments, referring to FIGS. 6 to 12 together with FIG. 4, the display device (see 1 of FIG. 1) according to one or more embodiments of the present disclosure may include: a substrate 100; at least one thin-film transistor T1 or T2 on the substrate 100; a light-emitting element 400 electrically connected to at least one thin-film transistor T1 or T2; and a first region B and a second region C located between the at least one thin-film transistor T1 or T2 and the light-emitting element 400, the first region B including the first conductive layer SD1, the second conductive layer SD2, and the third conductive layer SD3 sequentially stacked, and the second region C, spaced apart from the first region B, and including one or two of the first conductive layer SD1, the second conductive layer SD2, and the third conductive layer SD3, and a planarization layer SOG stacked on the one or two conductive layers. At this time, the third conductive layer SD3 of the first region B may be positioned at a higher level than the conductive layer located at the uppermost end of the second region C.

In the present specification, the expression ‘may be located at a higher level may mean that the distance measured in the stacking direction of the components of the display device 1, with reference to the substrate 100 in FIG. 4, is relatively large.

For example, as illustrated in FIG. 6, the first region B may include a first conductive layer SD1, a second conductive layer SD2, and a third conductive layer SD3 that are sequentially stacked, and the second region C may include the first conductive layer SD1, the third conductive layer SD3, and the planarization layer SOG that are sequentially stacked.

However, the present disclosure is not limited thereto, and various arrangements are possible as long as the planarization layer SOG is arranged on the conductive layer arranged at a low level relative to the substrate 100. For example, the first region B may include a first conductive layer SD1, a second conductive layer SD2, and a third conductive layer SD3 that are sequentially stacked, and the second region C may include a first conductive layer SD1, a second conductive layer SD2, and a planarization layer SOG that are sequentially stacked. Alternatively, the first region B may include the first conductive layer SD1, the second conductive layer SD2, and the third conductive layer SD3 that are sequentially stacked, and the second region C may include the first conductive layer SD1 and the planarization layer SOG that are sequentially stacked.

That is, the third conductive layer SD3 positioned at the uppermost end of the first region B may be positioned at a higher level than the conductive layer positioned at the uppermost end of the second region C, and the planarization layer SOG may be positioned on the conductive layer located at the uppermost end of the second region C. In some embodiments, the planarization layer SOG may not be arranged on the third conductive layer SD3 of the first region B.

Alternatively, the third conductive layer SD3 of the first region B may not overlap with the planarization layer SOG, and the planarization layer SOG may be arranged on the conductive layer positioned at the uppermost end of the second region C. However, for the convenience of explanation, the following description will be based on the conductive layers arranged in FIG. 6.

Meanwhile, a method of manufacturing the display device 1 according to one or more embodiments of the present disclosure may include forming at least one thin-film transistor T1 or T2 on the substrate 100, forming the first conductive layer SD1 on an insulating layer covering the at least one thin-film transistor T1 or T2 and patterning the same, forming the second conductive layer SD2 on the first insulating layer I1 covering the patterned first conductive layer SD1 and patterning the same, forming the third conductive layer SD3 on the second insulating layer I2 covering the patterned second conductive layer SD2, forming the planarization layer SOG on the third conductive layer SD3, depositing the photoresist PR on the planarization layer SOG and the third conductive layer SD3 and then patterning the photoresist PR, and etching the planarization layer SOG and the third conductive layer SD3 using the patterned photoresist PR as a mask, and forming the light-emitting element 400 electrically connected to the third conductive layer SD3 which has been etched.

The stacked shape of the first conductive layer SD1, the second conductive layer SD2, and the third conductive layer SD3 of the display device 1, which has undergone the operations of forming the first conductive layer SD1 on the insulating layer covering at least one thin-film transistor T1 or T2 and patterning the same, forming the second conductive layer SD2 on the first insulating layer I1 covering the patterned first conductive layer SD1 and patterning the same, and forming the third conductive layer SD3 on the second insulating layer I2 covering the patterned second conductive layer SD2, may be, for example, the shape illustrated in FIG. 7. As illustrated in FIG. 7, when stacking the first conductive layer SD1, the second conductive layer SD2, and the third conductive layer SD3, there may be a region with a step between the conductive layers.

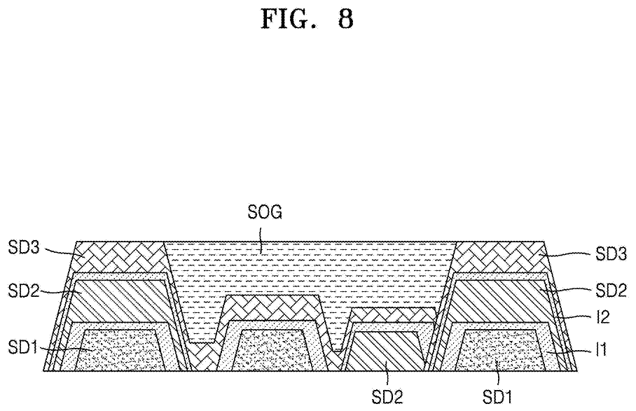

Referring to FIG. 8, the area having a step between the conductive layers may be filled by forming the planarization layer SOG on the third conductive layer SD3. The planarization layer SOG may include at least one of, for example, siloxane, silica, poly-silsesquioxane, silicon oxycarbide, or low-k silicon. In some embodiments, the planarization layer SOG may include, for example, a solution-based hard mask material. The planarization layer SOG may be deposited on the third conductive layer SD3 by, for example, spin coating.

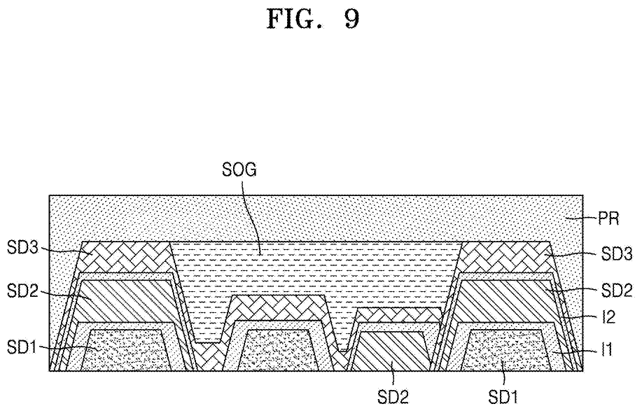

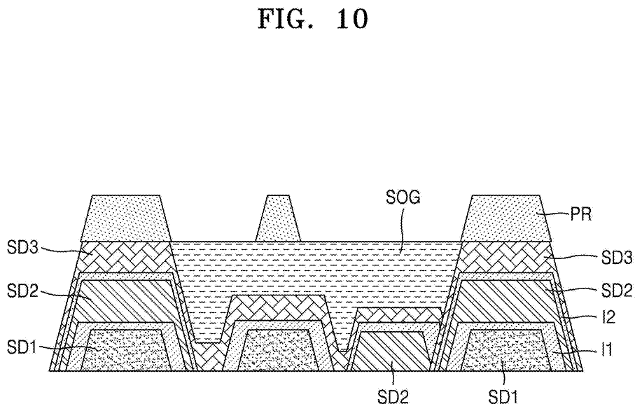

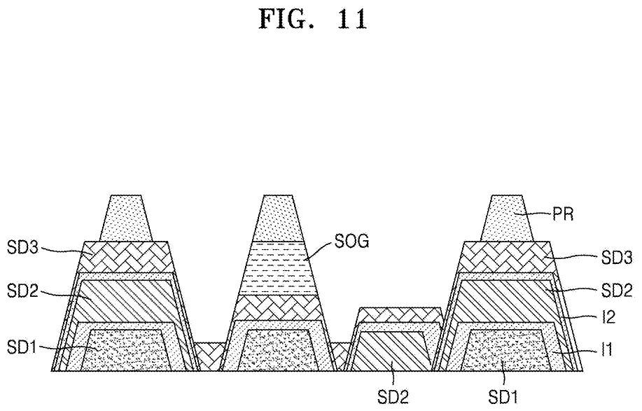

Referring to FIGS. 9 and 10, after depositing a photoresist PR on the planarization layer SOG and the third conductive layer SD3, which have been planarized by the planarization layer SOG, the photoresist PR may be patterned. Thereafter, as shown in FIG. 11, the planarization layer SOG may be etched using the patterned photoresist PR as a mask. At this time, the etching of the planarization layer SOG may be performed by dry etching.

In such a case, the patterning process of the photoresist PR and the etching process of the planarization layer SOG may be performed using the same mask. That is, rather than performing chemical mechanical polishing on the planarization layer SOG, the planarization layer SOG may be etched using the mask used in photoresist PR patterning. At this time, as described above, the patterned photoresist PR may also mask the planarization layer SOG.

As a result, the upper surface of the conductive layer located at the uppermost end of the second region C may conform to the lower surface of the planarization layer SOG. For example, the upper surface of the third conductive layer SD3 of the second region C may conform to the lower surface of the planarization layer SOG.

In this specification, the term ‘conform between the upper surface of the conductive layer and the lower surface of the planarization layer SOG does not necessarily mean that the upper surface of the conductive layer and the lower surface of the planarization layer SOG are in perfect physical conformity, but may include a case where a certain degree of deviation exists in the shapes of the upper surface of the conductive layer and the lower surface of the planarization layer SOG due to process tolerances. For example, due to tolerances, the length of the lower surface of the planarization layer SOG, as measured in a second direction (see y-direction in FIG. 1), may be about 1 μm shorter than the length of the upper surface of the third conductive layer SD3 in the second region C.

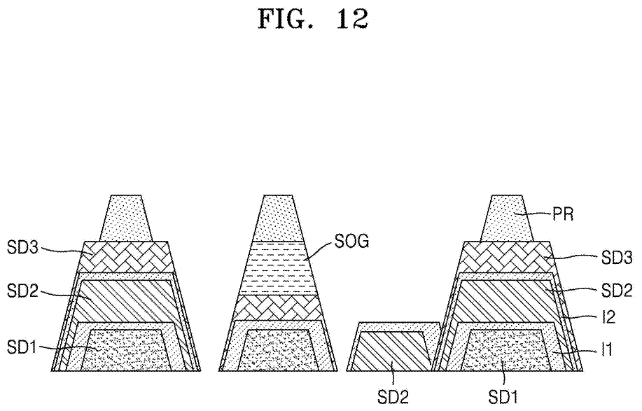

Referring to FIG. 12, the third conductive layer SD3 may be etched using the mask employed in a patterning process of a photoresist PR or using the patterned photoresist PR itself as a mask. At this time, the etching of the third conductive layer SD3 may be performed by dry etching. In some embodiments, when etching the third conductive layer SD3, the third conductive layer SD3 between the first region B and the second region C may be etched and removed, so that a space X between the first region B and the second region C may be formed.

Thereafter, the photoresist PR is stripped, thereby fabricating, as illustrated in FIG. 6, the display device 1 including the first region B in which the first conductive layer SD1, the second conductive layer SD2, and the third conductive layer SD3 are sequentially stacked, and the second region C, spaced apart from the first region B, in which the first conductive layer SD1, the third conductive layer SD3, and the planarization layer SOG are sequentially stacked.

Unlike conventional display devices manufactured by using the planarization layer SOG without filling the space X between the first region B and the second region C, the display device 1 manufactured in this manner poses no risk of photoresist PR remaining in the space X between the first region B and the second region C, and thus the metal pattern under the photoresist PR also does not remain, thereby reducing or preventing the likelihood of the formation of an unintended current path. Accordingly, the stability of the display device 1 and an electronic device including the same can be increased

In some embodiments, the integration level of the display device 1 can be improved by sequentially stacking conductive layers SD1, SD2, and SD3 that supply source current or drain current to the thin-film transistor T1 or T2 in a vertical direction (indicating the stacking direction of the components). For example, the resolution of the display device 1 may be about 1300 pixels per inch (ppi) to about 7000 ppi.

Meanwhile, in FIGS. 6 to 12, the second region C is illustrated and described as having the first conductive layer SD1, the third conductive layer SD3, and the planarization layer SOG sequentially stacked. However, in one or more other embodiments, the second region C may instead have the second conductive layer SD2, the third conductive layer SD3, and the planarization layer SOG sequentially stacked.

Meanwhile, the heights of the first region B and the second region C of the display device 1 according to one or more embodiments of the present disclosure may be the same. In this regard, “the height of the first region B” may refer to a difference in distance from the substrate 100 to the upper surface of the third conductive layer SD3 in the first region B, and “the height of the second region C” may refer to a difference in distance from the substrate 100 to the upper surface of the planarization layer SOG in the second region C.

In some embodiments, the expression that “the height of the first region B and the height of the second region C are the same” or “substantially equal” does not mean that the heights are physically identical, but rather that a certain degree of difference may exist between the height of the first region B and the height of the second region C. At this time, as will be described later, in case that the flatness of the pixel electrode 410 of the light-emitting element 400 that may be formed on the third conductive layer SD3 and the planarization layer SOG can be improved, there may be a certain degree of difference in the heights of the first region B and the second region C. For example, the difference in height between the first region B and the second region C may fall within a range of about 10% or less.

In some embodiments, an organic insulating layer (see VIA in FIG. 4) may be formed on and may cover the third conductive layer SD3 of the first region B and the planarization layer SOG of the second region C. The light-emitting element 400 electrically connected to the third conductive layer SD3 may be arranged on the organic insulating layer VIA.

In some embodiments, the pixel electrode 410 of the light-emitting element 400 may be located on the third conductive layer SD3 and the planarization layer SOG arranged at the same or similar levels, and may be electrically connected to the third conductive layer SD3. In this way, in case that the organic insulating layer VIA is located on the third conductive layer SD3 and the planarization layer SOG arranged at the same or similar height, and the pixel electrode 410 is located on the organic insulating layer VIA, the flatness of the pixel electrode 410 can be improved. In this regard, the term “flatness” may mean a difference between a maximum height and a minimum height of a surface. In some embodiments, the expression that “flatness is low” may mean that the difference between the maximum height and the minimum height of the surface is large. The term “high flatness” means that the difference between the maximum height and the minimum heights of the surface is small.

In case that the flatness of the pixel electrode 410 is relatively low, unevenness in luminescence efficiency by viewing angle may occur, and optical characteristics, such as poor reflection color deviation, may be deteriorated due to uneven reflection of the pixel electrode 410. However, in the display device 1 according to embodiments of the present disclosure, the flatness of the pixel electrode 410 is improved, whereby the light emission efficiency according to the viewing angle and optical characteristics of the display device 1 and the electronic device including the same may be improved.

Meanwhile, the planarization layer SOG may include at least one of siloxane, silica, polysilsesquioxane, silicon oxycarbide, or low-k silicon. Unlike the photoresist PR, the planarization layer SOG including such a material may not deteriorate the characteristics of the display device 1 even if the planarization layer SOG remains between the conductive layers SD1, SD2, and SD3, but rather can improve the flatness of the pixel electrode 410 as described above.

In some embodiments, the planarization layer SOG including the material described above may be easily removed during an etching process, similar to the first gate-insulating layer GI1, the second gate-insulating layer GI2, the third gate-insulating layer GI3, the fourth gate-insulating layer GI4, the first insulating layer I1 and the second insulating layer I2, each of which may include silicon nitride and/or silicon oxide, as described with reference to FIG. 4.

That is, even if the planarization layer SOG including such material remains without being removed, the characteristics of the display device 1 may not deteriorate and the removal thereof is easy.

Meanwhile, when describing one or more embodiments of the present disclosure, the stacked configuration of FIG. 4 was described as the basis, but the present disclosure is not limited thereto. The present disclosure may be applied to any stacked configuration in which conductive layers spaced apart from each other are arranged between the thin-film transistor T1 or T2 and the light-emitting element 400, and the photoresist PR may remain between the spaced conductive layers. For example, in case that conductive layers spaced apart from each other are arranged between a thin-film transistor T1 or T2 and a light-emitting element 400, as described above, the planarization layer SOG is first arranged on the conductive layer located at the uppermost layer, and then, the planarization layer SOG is etched using the same mask as that used for patterning the photoresist PR, and the unmasked conductive layers are etched to reduce or prevent the photoresist remaining in the space between the conductive layers.

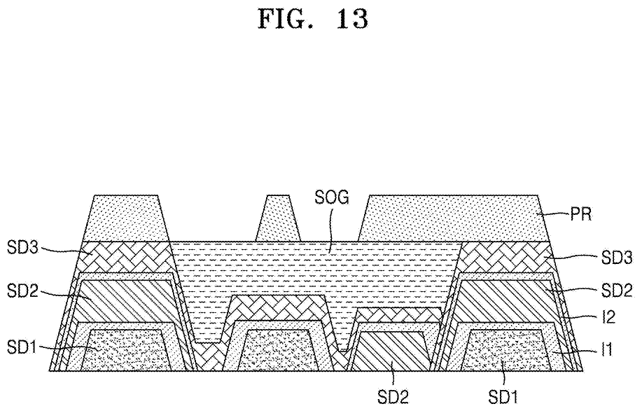

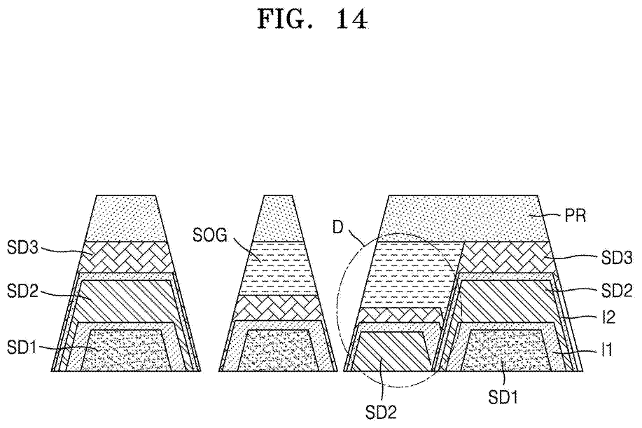

FIG. 13 and FIG. 14 are cross-sectional views schematically illustrating one or more embodiments of a stacked shape of conductive layers according to one or more other embodiments of the present disclosure. When describing FIGS. 13 and 14, only the parts that are different from those described above in FIGS. 6 to 12 are described.

First, referring to FIG. 14, a display device 1 according to one or more other embodiments of the present disclosure may include a first region B in which a first conductive layer SD1, a second conductive layer SD2, and a third conductive layer SD3 are sequentially stacked, a second region C spaced apart from the first region B, in which the first conductive layer SD1, the third conductive layer SD3, and the planarization layer SOG are sequentially stacked, and a third region D spaced apart from the second region C, in which the second conductive layer SD2, the third conductive layer SD3, and the planarization layer SOG are sequentially stacked.

However, as one or more embodiments, as long as the types of conductive layers stacked in the third region D are different from the types of conductive layers stacked in the second region C, and the height of the conductive layer stacked at the uppermost end of the third region D is lower than the height of the third conductive layer SD3 of the first region B, the third region D may have various stacked structures.

For example, in case that the second region C includes the second conductive layer SD2, the third conductive layer SD3, and the planarization layer SOG that are sequentially stacked, the third region D may include the second conductive layer SD2 and the planarization layer SOG that are sequentially stacked.

At this time, the heights of the first region B, the second region C, and the third region D may all be the same. However, this is not limited thereto, and the heights of the first region B, the second region C, and the third region D may differ to some extent. For example, the heights of the first region B, the second region C, and the third region D may each differ by less than about 10%.

A method of manufacturing a display device 1 according to one or more other embodiments of the present disclosure may include, during patterning of the photoresist PR formed on the third conductive layer SD3 and the planarization layer SOG, allowing the photoresist PR on the planarization layer SOG in the third region D to remain without being removed, as illustrated in FIG. 13.

As in one or more other embodiments of the present disclosure, in case that an organic insulating layer VIA is located on the third conductive layer SD3 and the planarization layer SOG of the first region B, the second region C, and the third region D having the same or similar height, and the pixel electrode 410 is located on the organic insulating layer VIA, the flatness of the pixel electrode 410 can be further improved. As a result, the flatness of the pixel electrode 410 is improved, so that the light emission efficiency and optical characteristics of the display device 1 and the electronic device including the same can be improved according to the viewing angle.

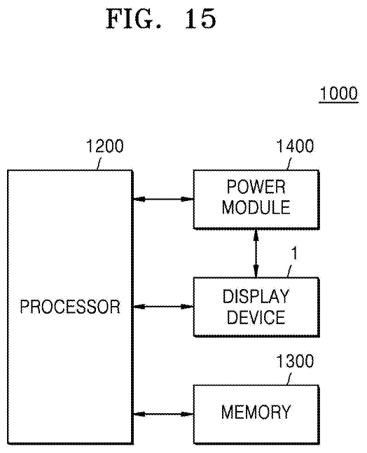

FIG. 15 is a block diagram of an electronic device according to one or more embodiments.

Referring to FIG. 15, an electronic device 1000 according to one or more embodiments may include a display device 1, a processor 1200, a memory 1300, and a power module 1400.

The display device 1 may receive data from the processor 1200 and provide visual information. The display device 1 may be a display device 1 according to the embodiments of the present disclosure described above.

The processor 1200 may include at least one of a central processing unit (CPU), an application processor (AP), a graphic processing unit (GPU), a communication processor (CP), an image signal processor (ISP), or a controller. For example, the processor 1200 may operate by executing at least one program.

Data information suitable for the operation of the processor 1200 or display device 1 may be stored in the memory 1300. For example, the memory 1300 may store the at least one program. In case that the processor 1200 executes an application stored in the memory 1300, an image data signal and/or an input control signal is transmitted to the display device 1, and the display device 1 may process the received signal and output image information through a display screen.

The power module 1400 may include a power supply module, such as a power adapter or a battery device, and a power conversion module that converts power supplied by the power supply module to generate power required for the operation of the electronic device 1000. For example, the power module 1400 may supply power to the display device 1.

At least one of the components of the electronic device 1000 may be included in the display device 1 according to the embodiments. In some embodiments, some of the individual modules functionally included within a single module may be included within the display device 1 and others may be provided separately from the display device 1.

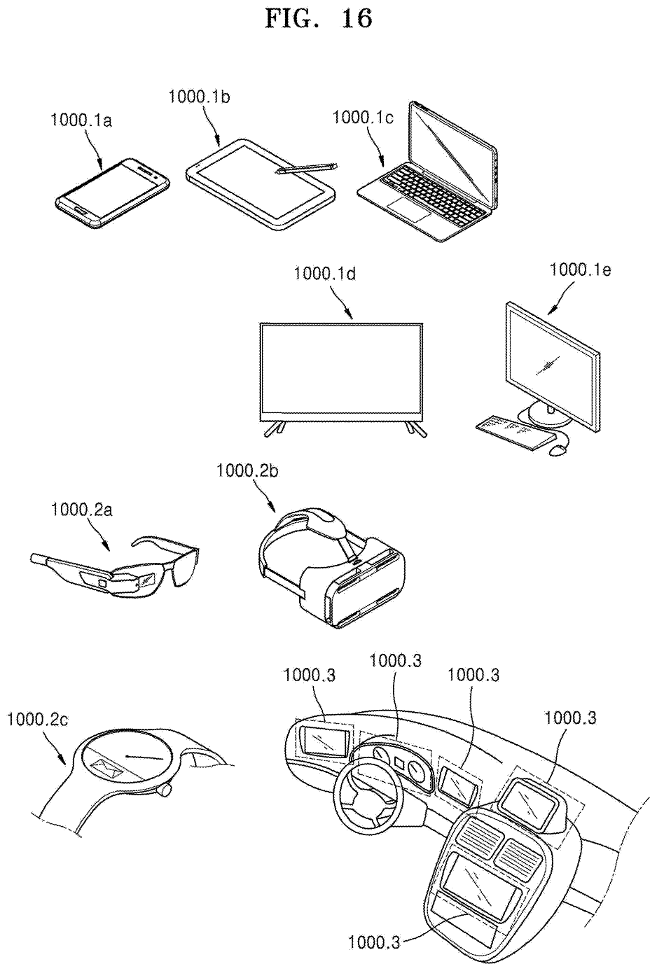

FIG. 16 is a schematic diagram of an electronic device according to various embodiments.

Referring to FIG. 16, various electronic devices to which display devices according to embodiments of the present disclosure are applied may include not only image display electronic devices, such as a smartphone 1000.1a, a tablet PC 1000.1b, a laptop 1000.1c, a TV 1000.1d, and a desk monitor 1000.1e, but also wearable electronic devices including display devices, such as smart glasses 1000.2a, a head-mounted display 1000.2b, and a smart watch 1000.2c, and vehicle electronic devices including display devices, such as a center information display (CID) and a room mirror display located on a dashboard, center fascia, and dashboard of an automobile 1000.3.

Each of the embodiments described above can be implemented independently, although the structure of each embodiment can be applied in combination to other embodiments.

Although the present disclosure has been described with reference to the embodiments illustrated in the drawings, these are merely examples, and those skilled in the art will understand that various modifications and other equivalent embodiments are possible therefrom. Therefore, the true technical protection scope of the present disclosure should be determined by the technical idea of the appended patent claims.

The implementations described in the embodiments are merely embodiments and do not limit the scope of the examples in any way. In some embodiments, in case that there is no specific mention, such as “essential” or “important,” it may not be a component absolutely necessary for the application of the present disclosure.

The use of the term “above” and similar referential terms in the specification of embodiments (especially in the claims) may refer to both the singular and the plural.

In some embodiments, in case that a range is described in one or more embodiments, it is considered that the disclosure includes an individual value that falls within the range (unless otherwise stated), and it is the same as describing each individual value that constitutes the range in the detailed description.

Finally, unless there is an explicit description of the order or sequence of operations constituting the method according to one or more embodiments, the operations can be performed in any suitable order. The embodiments are not necessarily limited to the order in which the operations are described.

Any use of embodiments or exemplary terms in the embodiments is merely intended to elaborate the embodiments and is not intended to limit the scope of the embodiments, unless otherwise defined by the claims. Furthermore, those skilled in the art will appreciate that various modifications, combinations and variations can be made according to design conditions and factors within the scope of the appended claims or their equivalents.

According to embodiments of the present disclosure, by reducing or preventing remaining photoresist between conductive layers that are arranged between a thin-film transistor and a light-emitting element and that supply source current or drain current to the thin-film transistor, the stability of a display device and an electronic device including the same can be improved by reducing or preventing residual current flowing through a underlying conductive layer that may remain under the remaining photoresist.

The flatness of the pixel electrode can be improved by arranging the pixel electrode on the third conductive layer and the planarization layer.

However, the effects obtainable through the present disclosure are not limited to the effects described above, and other technical effects not mentioned will be clearly understood by those skilled in the art from the following detailed description of the disclosure.

What is claimed is:

1. A display device comprising:
a substrate;
a thin-film transistor above the substrate;
a light-emitting element electrically connected to the thin-film transistor;
a first region between the thin-film transistor and the light-emitting element, and comprising a first conductive layer, a second conductive layer, and a third conductive layer sequentially stacked; and
a second region between the thin-film transistor and the light-emitting element, spaced apart from the first region, and comprising one or two of the first conductive layer, the second conductive layer, or the third conductive layer and a planarization layer stacked thereabove,
wherein the third conductive layer of the first region is at a higher level than an uppermost one of the one or two of the first conductive layer, the second conductive layer, or the third conductive layer of the second region, and
wherein an upper surface of the uppermost one of the one or two of the first conductive layer, the second conductive layer, or the third conductive layer of the second region conforms to a lower surface of the planarization layer.

2. The display device of claim 1, wherein a height of the first region is substantially equal to a height of the second region.

3. The display device of claim 2, wherein the light-emitting element comprises a pixel electrode above the third conductive layer of the first region and the planarization layer of the second region, a common electrode, and an intermediate layer between the pixel electrode and the common electrode and comprising an organic material, and
wherein the third conductive layer of the first region and the planarization layer of the second region are at a same level.

4. The display device of claim 3, wherein the pixel electrode is electrically connected to the third conductive layer of the first region.

5. The display device of claim 1, wherein the third conductive layer of the first region does not overlap with the planarization layer.

6. The display device of claim 1, further comprising a third region spaced apart from the second region and comprising the second conductive layer, the third conductive layer, and the planarization layer sequentially stacked.

7. The display device of claim 6, wherein a height of the second region is substantially equal to a height of the third region.

8. The display device of claim 6, further comprising:
a first insulating layer between the first conductive layer of the first region and the second conductive layer of the first region; and
a second insulating layer between the second conductive layer of the first region and the third conductive layer of the first region.

9. The display device of claim 8, wherein the second insulating layer is between the second conductive layer of the third region and the third conductive layer of the third region.

10. A method of manufacturing a display device, the method comprising:
forming a thin-film transistor above a substrate;
forming a first conductive layer above an insulating layer covering the thin-film transistor, and patterning the first conductive layer;
forming a second conductive layer above a first insulating layer covering a patterned first conductive layer, and patterning the second conductive layer;
forming a third conductive layer above a second insulating layer covering a patterned second conductive layer;
forming a planarization layer above the third conductive layer;
depositing a photoresist above the planarization layer and the third conductive layer;
patterning the photoresist;
etching the planarization layer and the third conductive layer using a patterned photoresist as a mask; and
forming a light-emitting element electrically connected to an etched third conductive layer,
wherein a first region and a second region are spaced apart between the thin-film transistor and the light-emitting element, the first region comprising the first conductive layer, the second conductive layer, and the third conductive layer sequentially stacked, and the second region comprising the first conductive layer, the third conductive layer, and the planarization layer are sequentially stacked.

11. The method of claim 10, further comprising etching the third conductive layer to remove a portion of the third conductive layer between the first region and the second region.

12. The method of claim 10, wherein a patterned planarization layer is in the second region.

13. The method of claim 10, wherein a height of the first region is equal to a height of the second region.

14. The method of claim 13, wherein the light-emitting element comprises a pixel electrode above the etched third conductive layer and the planarization layer, a common electrode, and an intermediate layer between the pixel electrode and the common electrode and comprising an organic material, and
wherein the etched third conductive layer and the planarization layer are at a same level.

15. The method of claim 10, wherein the etching of the planarization layer and the third conductive layer comprises dry etching.

16. The method of claim 10, further comprising, after the etching the planarization layer and the third conductive layer, stripping the photoresist.

17. The method of claim 10, wherein the planarization layer comprises at least one of siloxane, silica, polysilsesquioxane, silicon oxycarbide, or low-k silicon.

18. The method of claim 10, wherein the etching the planarization layer and the third conductive layer comprises forming a third region spaced apart from the second region and comprising the second conductive layer, the third conductive layer, and the planarization layer are sequentially stacked.

19. The method of claim 18, wherein a height of the second region is substantially equal to a height of the third region.

20. An electronic device comprising:
a memory configured to store at least one program;
a processor configured to operate by executing the at least one program;
a display device configured to receive data from the processor and to provide visual information; and
a power module configured to supply power to the display device,
wherein the display device comprises:
a substrate;
a thin-film transistor above the substrate;
a light-emitting element electrically connected to the thin-film transistor; and
a first region and a second region spaced apart between the thin-film transistor and the light-emitting element, the first region comprising a first conductive layer, a second conductive layer, and a third conductive layer sequentially stacked, and the second region comprising one or two of the first conductive layer, the second conductive layer, or the third conductive layer, and a planarization layer thereabove,
wherein the third conductive layer of the first region is at a higher level than an uppermost one of the one or two of the first conductive layer, the second conductive layer, or the third conductive layer of the second region, and
wherein an upper surface of the uppermost one of the one or two of the first conductive layer, the second conductive layer, or the third conductive layer of the second region conforms to a lower surface of the planarization layer.
